(19) United States
(12) Patent Application Publication
(10) Pub. No.: US 2016/0358770 A1
(43) Pub. Date: Dec. 8, 2016

(54) METHOD FOR FORMING PATTERN OF SEMICONDUCTOR DEVICE

(71) Applicant: Samsung Electronics Co., Ltd., Suwon-si (KR)

(72) Inventors: JEON BYUNG-JUN, Suwon-si (KR); KANG DAE-YONG, Suwon-si (KR); KIM JAE-HEE, Gimpo-si (KR); KIM HEE-JUNG, Seongnam-si (KR); DO SIN-HAE, Busan (KR); PARK JOON-SOO, Seongnam-si (KR); CHO SEOK-WON, Suwon-si (KR); HA SOON-MOK, Hwaseong-si (KR)

(21) Appl. No.: 15/134,459

(22) Filed: Apr. 21, 2016

(30) Foreign Application Priority Data
Jun. 8, 2015 (KR) 10-2015-0080549

(51) Int. Cl. H01L 21/027; G03F 1/76; H01L 21/311; H01L 21/308; H01L 21/3213

(52) U.S. Cl. CPC H01L 21/0276; H01L 21/3081; H01L 21/32139; H01L 21/31144; G03F 1/76

(57) ABSTRACT

Methods include forming an anti-reflection layer containing a photosensitive material directly on an etching layer, forming a photoresist layer directly on the anti-reflection layer, and removing portions of the photoresist layer and the anti-reflection layer to form a pattern. Spacers are formed on sidewalls of the pattern and the pattern is removed to leave the spacers. The etching layer is patterned using the spacers as a mask. Forming an anti-reflection layer may include forming an inorganic anti-reflection layer directly on the etching layer and forming an organic anti-reflection layer directly on the inorganic anti-reflection layer.

### CROSS-REFERENCE TO RELATED APPLICATION

This application claims priority from Korean Patent Application No. 10-2015-0080549 filed on Jun. 8, 2015 in the Korean Intellectual Property Office, the disclosure of which is incorporated herein by reference in its entirety.

### BACKGROUND

1. Technical Field

The present inventive concept relates to a method for forming a pattern of a semiconductor device.

2. Description of the Related Art

In accordance with increased integration of semiconductor devices, line widths of patterns included in the semiconductor devices have been reduced. Thus, in order to form fine patterns during the manufacturing of semiconductor devices, a MPT (Multi Patterning Technology) process and the like have been developed and, in particular, a SADP (Self Aligned Double Patterning) process. The SADP process is a process that includes forming a mask pattern having a line width narrower than that of a mask pattern formed by a lithography process and forming a fine pattern using the mask pattern. However, because the SADP process uses a hard mask layer, the process may be complicated and have undesirably high cost.

### SUMMARY

Some embodiments of the inventive concept provide methods including providing a substrate comprising an etching layer, an anti-reflection layer containing a photosensitive material directly on the etching layer, and a photoresist layer directly on the anti-reflection layer. A first pattern is formed by etching the photoresist layer and the anti-reflection layer. A spacer layer is formed on upper and sidewall surfaces of the first pattern and a portion of the spacer layer is removed to expose the upper surface of the first pattern. The exposed first pattern is removed and the etching layer is patterned using remaining portions of the spacer layer as a mask to form a second pattern.

In some embodiments, the anti-reflection layer provides hydrogen ions to the photoresist layer. The anti-reflection layer may include a photo acid generator (PAG).

Forming the first pattern may include removing a portion of the photoresist layer in an in-situ process and removing a portion of the anti-reflection layer in a succeeding process. In some embodiments, forming the first pattern may include removing a portion of the photoresist layer using a photolithography process and removing a portion of the anti-reflection layer using a remainder of the photoresist layer as a mask. In some embodiments, an upper portion of the spacer layer is removed using an etch-back process. The anti-reflection layer may have a multilayer structure.

Further embodiments provide methods including forming an etching layer on a substrate, forming an inorganic anti-reflection layer directly on the etching layer, forming an organic anti-reflection layer directly on the inorganic anti-reflection layer, forming a photoresist layer directly on the organic anti-reflection layer, forming a first pattern by removing portions of the organic anti-reflection layer and the photoresist layer, forming a spacer on a sidewall of the first pattern, removing the first pattern, and removing a portion of the inorganic anti-reflection layer using the spacer as a mask to form a second pattern.

The organic anti-reflection layer may provide hydrogen ions to the photoresist layer. The organic anti-reflection layer may include a photosensitive material. The organic anti-reflection layer may include a photo acid generator (PAG).

In some embodiments, forming the first pattern may include removing a portion of the photoresist layer in an in-situ process and removing a portion of the organic anti-reflection layer in a succeeding process. Forming the first pattern may include removing a portion of the photoresist layer using a photolithography process and removing a portion of the organic anti-reflection layer using a remainder of the photoresist layer as a mask. The methods may further include patterning the etching layer using the second pattern as a mask.

Still further embodiments provide methods including forming an anti-reflection layer containing a photosensitive material directly on an etching layer, forming a photoresist layer directly on the anti-reflection layer, and removing portions of the photoresist layer and the anti-reflection layer to form a pattern. Spacers are formed on sidewalls of the pattern and the pattern is removed to leave the spacers. The etching layer is patterned using the spacers as a mask. Forming an anti-reflection layer may include forming an inorganic anti-reflection layer directly on the etching layer and forming an organic anti-reflection layer directly on the inorganic anti-reflection layer.

### BRIEF DESCRIPTION OF DRAWINGS

FIG. 1 through FIG. 8 illustrate intermediate-level structures illustrating operations for forming a pattern of a semiconductor device according to some embodiments of the present inventive concept.

FIG. 9 and FIG. 10 are views illustrating a conventional photolithography process using a positive photoresist.

FIG. 11 and FIG. 12 are views illustrating a conventional photolithography process using a negative photoresist.

FIG. 13 through FIG. 15 are views illustrating photolithography process using a photosensitive anti-reflection layer according to some embodiments of the present inventive concept.

FIG. 16 through FIG. 21 are intermediate-level views illustrating operations for forming a pattern of a semiconductor device according to some embodiments of the present inventive concept.

FIG. 22 is a plan view of a NAND flash memory device formed using operations for forming a pattern of a semiconductor device according to some embodiments of the present inventive concept.

FIG. 23 is a cross-sectional view taken along line I-I′ of FIG. 22.

FIG. 24 is a block diagram of an electronic system including a semiconductor device formed using operations for forming a pattern of a semiconductor device according to some embodiments of the present inventive concept.

FIG. 25 and FIG. 26 are exemplary semiconductor systems to which a semiconductor device formed using operations for forming a pattern of a semiconductor device according to some embodiments of the present inventive concept is applicable.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

The present invention will be described with reference to perspective views, cross-sectional views, and/or plan views, in which preferred embodiments of the invention are shown. Thus, the profile of an exemplary view may be modified according to manufacturing techniques and/or allowances. That is, the following description embodiments of the invention is not intended to limit the scope of the present invention but covers all changes and modifications that can be caused due to a change in manufacturing process. Thus, regions shown in the drawings are illustrated in schematic form and the shapes of the regions are presented simply by way of illustration and not as a limitation.

Operations for forming a pattern of a semiconductor device described hereinafter relate to a MPT (Multi Patterning Technology) process aiming at simplifying process stages and reducing process costs. In particular, some embodiments of the present inventive concept include forming a mandrel pattern using a photoresist layer without a hard mask layer used in a general MPT process and forming a spacer on a sidewall of the pattern to thereby perform patterning thereon. Accordingly, process stages may be reduced and process costs may be decreased.

In a process of photo-sensing a photoresist layer, a pattern having an inclined sidewall is generally formed. However, in some embodiments of the present inventive concept, a photosensitive anti-reflection layer may be formed on a lower portion of a photoresist layer in order to solve such a defect. The photosensitive anti-reflection layer is formed on the lower portion of the photoresist layer, whereby a sidewall of a pattern formed in the process of photo-sensing a photoresist layer may have a substantially vertical shape. Accordingly, a process margin of a photolithography process may be increased and in particular, DoF (depth of focus) and lifting margins may be increased.

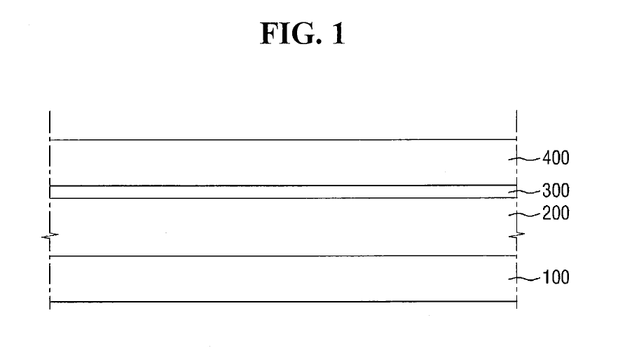

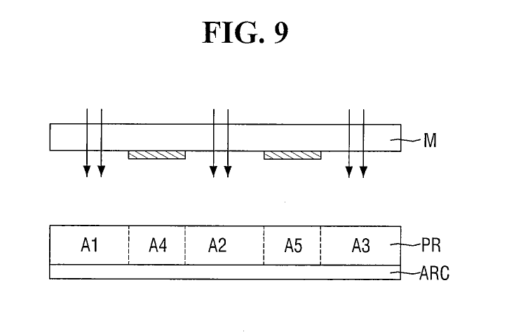

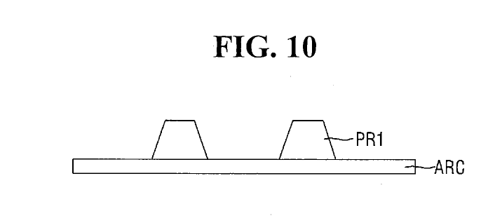

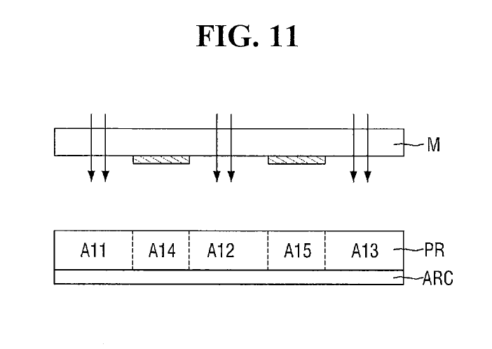

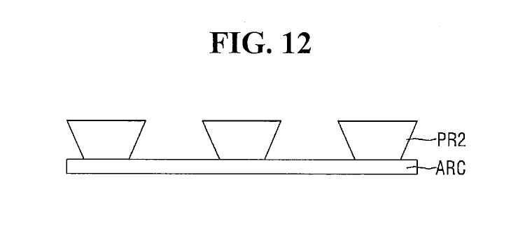

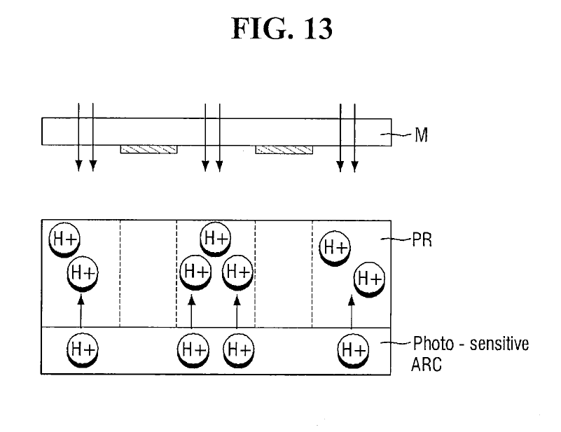

FIG. 1 through FIG. 8 are intermediate-level views illustrating operations for forming a pattern of a semiconductor device according to some embodiments of the present inventive concept. FIG. 9 and FIG. 10 are views illustrating a conventional photolithography process using a positive photoresist. FIG. 11 and FIG. 12 are views illustrating a conventional photolithography process using a negative photoresist. FIG. 13 through FIG. 15 are views illustrating a photolithography process using a photosensitive anti-reflection layer according to some embodiments of the present inventive concept.

Referring to FIG. 1 first, an etching layer 200 (a layer to be etched), an anti-reflection layer 300, and a photoresist layer 400 may be sequentially stacked on a substrate 100. The anti-reflection layer 300 may contain a photosensitive material and may be disposed between the etching layer 200 and the photoresist layer 400. That is, the anti-reflection layer 300 may be disposed to directly contact the etching layer 200 and the photoresist layer 400. In some embodiments according to the present inventive concept, since a hard mask layer such as a spin-on hard mask (SOH), an amorphous carbon layer (ACL) or the like is not used, the anti-reflection layer 300 may be formed on the etching layer 200 so as to be in direct-contact therewith.

The substrate 100 may be formed of one or more semiconductor materials, such as Si, Ge, SiGe, GaP, GaAs, SiC, SiGeC, InAs and/or InP. In some embodiments, the substrate 100 may be a silicon on insulator (SOI) substrate or a germanium on insulator (GOI) substrate. IN some embodiments, the substrate 100 may be a rigid substrate, such as a display glass substrate or the like, or a flexible plastic substrate such as polyimide, polyester, polycarbonate, polyethersulfone, polymethylmethacrylate, polyethylenenaphthalate, polyethyleneterephthalate or the like.

Various structures may be further formed on the substrate 100. For example, a conductive layer containing a metal, a metallic nitride, a metallic silicide or the like. A conductive structure such as an electrode, an insulating layer and the like may be further formed. Although a case in which the etching layer 200 is further formed on the substrate 200 is illustrated, the etching layer 200 may not be formed in cases in which an etching object is the substrate 100.

The etching layer 200 may be formed by using a plasma-enhanced chemical vapor deposition (PECVD) process, a spin coating process, a high density plasma chemical vapor deposition (HDP-CVD) process or the like, using PSG (phosphor silicate glass), BPSG (boro-phosphor silicate glass), USG (undoped silicate glass), TEOS (tetra ethyl ortho silicate), PE-TEOS (plasma enhanced-TEOS) and HDP-CVD (high density plasma-chemical vapor deposition) oxides, porous oxides such as LK (low-k), ULK (ultra low-k) or the like, used in BEOL (back-end of line), or silicon nitrides.

In some embodiments, the etching layer 200 may be an insulating layer or a conductive layer configuring a semiconductor device and may be formed of a metallic material, a semiconductor material or an insulating material. For example, the etching layer 200 may be formed of tungsten, a tungsten silicide, polysilicon, aluminum or combinations thereof or the like. In some embodiments, the etching layer 200 may be formed of an oxide, a nitride, an oxynitride or the like.

The anti-reflection layer 300 may be formed on the etching layer 200 so as to be in direct contact therewith. The anti-reflection layer 300 may serve to prevent diffused reflection in a photolithography process for forming photoresist patterns 401. The anti-reflection layer 300 may be formed of an organic material and/or an inorganic material.

In some embodiments according to the present inventive concept, the anti-reflection layer 300 may contain a photosensitive material. In order to form various patterns 201 by patterning the etching layer 200, sidewalls of mask patterns (that is, spacer layer patterns 501) serving as a mask may have a substantially vertical slope. In the case that the mask patterns are asymmetrically and irregularly formed in profile, the patterns 201 formed on the substrate 100 may also have asymmetrical and irregular shapes.

When the spacer layer patterns 501 are formed using the photoresist patterns 401 as mandrel patterns, it is desirable to form the photoresist patterns 401 in sidewall shapes having a vertical slope, like a hard mask layer used in a general MPT process. However, a typical positive photoresist may have a positive slope after a photolithography process. In addition, a typical negative photoresist may have a negative slope after a photolithography process. In the case of performing the photolithography process using a typical positive photoresist or negative photoresist, asymmetrical and irregular spacer layer patterns 501 may be formed in a deposition process and a subsequent etching process of a spacer layer 500.

Problems regarding sidewall shapes of the photoresist patterns 401 may be solved by using the photosensitive anti-reflection layer 300. For example, in the case that a photo acid generator (PAG) is contained in the anti-reflection layer 300 as a photosensitive material, acid (that is, hydrogen ions) may be generated in an exposure region of the anti-reflection layer 300 by photoreaction of the PAG. The generated acid may be spread to a lower portion of the photoresist layer 400 to increase an acid concentration in the lower portion of the photoresist layer 400 having a relatively insufficient acid concentration. Accordingly, improvements may be made in such a manner that the photoresist patterns 401 formed in the photolithography process have sidewall shapes having a vertical slope.

In detail, referring to FIG. 9 and FIG. 10, a photolithography process using a positive photoresist is illustrated. When light exposure is performed on a photoresist PR disposed on an anti-reflection layer ARC using a mask M and subsequently, development is performed thereon, region A4 and region A5 may not be exposed to light and thus, may be formed as patterns PR1. In this case, sidewall shapes of the patterns PR1 may have a positive slope.

Referring to FIG. 11 and FIG. 12, a photolithography process using a negative photoresist is illustrated. When light exposure is performed on a photoresist PR disposed on an anti-reflection layer ARC using a mask M and subsequently, development is performed thereon, region A11, region A12 and region A13 may be exposed to light and thus, may be formed as patterns PR2. In this case, sidewall shapes of the patterns PR2 may have a negative slope.

Referring to FIG. 13 through FIG. 15, in some embodiments according to the present inventive concept, the spread of acid to a lower portion of a photoresist PR using a photosensitive anti-reflection layer ARC is illustrated. Accordingly, when the photoresist PR is exposed and developed, it may be formed to have a sidewall shape having a substantially vertical slope.

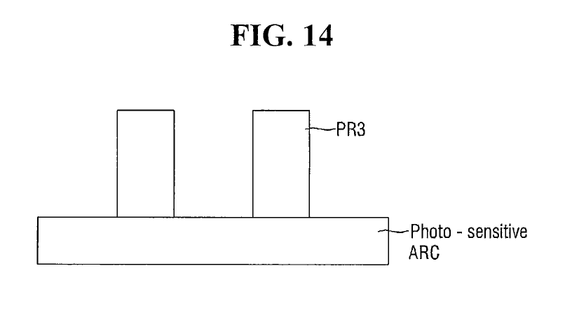

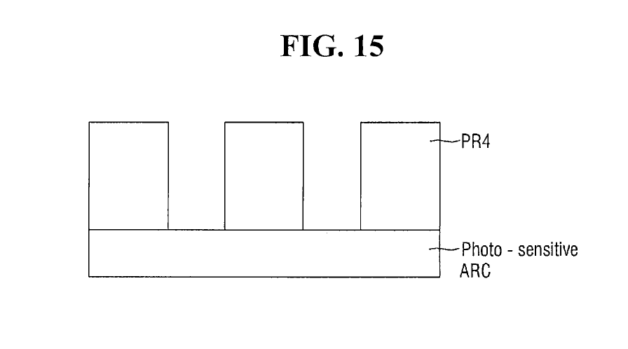

FIG. 14 illustrates patterns PR3 formed in the case of using a positive photoresist and FIG. 15 illustrates patterns PR4 formed in the case of using a negative photoresist.

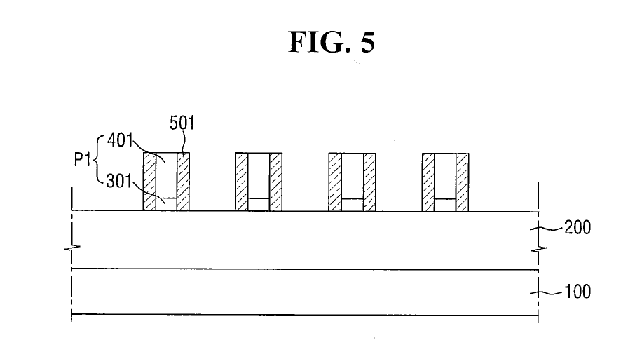

Additionally, when the spacer layer patterns 501 (see FIG. 5) having the same pitch are formed, in the case of using the positive photoresist as compared to the negative photoresist, image quality may be excellent in terms of optical properties, such that line width roughness (LWR) may be excellent and the lifting margin of the spacer layer patterns 501 may be improved. Thus, when a MPT process is performed in order to form the spacer layer patterns 501, it is effective to use the photosensitive anti-reflection layer ARC and the positive photoresist.

Referring to FIG. 1 again, the photoresist layer 400 may be formed on the anti-reflection layer 300.

The photoresist layer 400 may be formed of a material corresponding to an ArF-i (193 nm-i) or VUV (147 nm) chemically amplified resist. For example, the photoresist layer 400 may be formed of an acrylate polymer, a methacrylate polymer, a cyclo olefin-maleic anhydride copolymer (hereinafter, referred to as ‘a COMA polymer’) or hybrid polymers thereof.

The photoresist layer 400 may be formed by a spin-on deposition method, using the photoresist material. The photoresist layer 400 may be formed to have a thickness such that the anti-reflection layer 300 may be etched using the photoresist patterns 401 formed subsequently to the photoresist layer 400. For example, the photoresist material may be spin-coated and may be formed to have a thickness of 80 nm to 150 nm.

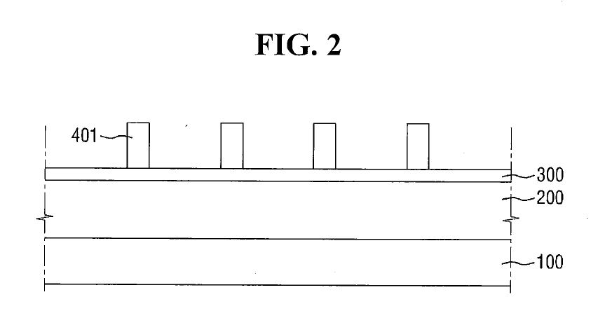

Referring to FIG. 2, the photoresist patterns 401 may be formed by etching the photoresist layer 400. In this case, by the photosensitive anti-reflection layer 300 disposed below the photoresist patterns 401, the photoresist patterns 401 may be formed to have sidewall shapes having a substantially vertical slope.

In detail, an exposure mask may be formed on an upper portion of the photoresist layer 400, and an exposure process of transferring a light source through a region of the exposure mask, containing no chrome patterns, may be performed. In this case, the chrome patterns of the exposure mask may have a predetermined pitch and may have a linear shape in which they are repeatedly formed in a first direction d1. The first direction d1 is a direction in which the patterns 201 are formed on the etching layer 200.

In the exposure process, a light source such as ArF-i (193 nm-i) or VUV (147 nm) may be used. For example, the exposure process may be performed with energy of 10 mJ/cm² to 50 mJ/cm² using an ArF-i light source.

A pre-bake process may be further performed prior to the exposure process. In addition, even after the exposure process, a post-bake process may be further performed. The bake process may be performed at a temperature of 90° C. to 110° C.

Subsequent to the exposure process, a development process may be performed on an exposure region of the photoresist layer 400 to thereby form the photoresist patterns 401.

The development process may be performed using approximately 2.4 wt % of a tetramethyl ammonia hydroxide (hereinafter, referred to as ‘TMAH’) solution, which is an alkaline developer. After performing the development process using the developer, a washing process of removing the developer using a conditioner solution may be further performed. The conditioner solution may be deionized water (DIW).

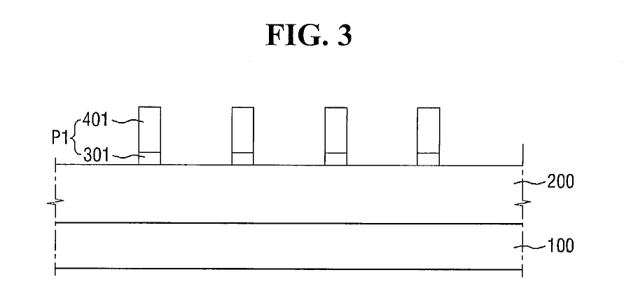

Referring to FIG. 3, the anti-reflection layer 300 may be etched using the photoresist patterns 401 as a mask to thereby form first patterns P1. The first patterns P1 may include the photoresist patterns 401 and anti-reflection layer patterns 301. That is, the first patterns P1 may include portions of the photoresist layer 400 and portions of the anti-reflection layer 300.

In this case, the forming of the first patterns P1 may be completed by removing portions of the photoresist layer 400 in an in-situ process and removing portions of the anti-reflection layer 300, in sequence. In addition, the first patterns P1 may be completed by removing portions of the photoresist layer 400 using a photolithography process and removing portions of the anti-reflection layer 300 using the remainder portions (that is, the photoresist patterns 401) of the photoresist layer 400 as a mask.

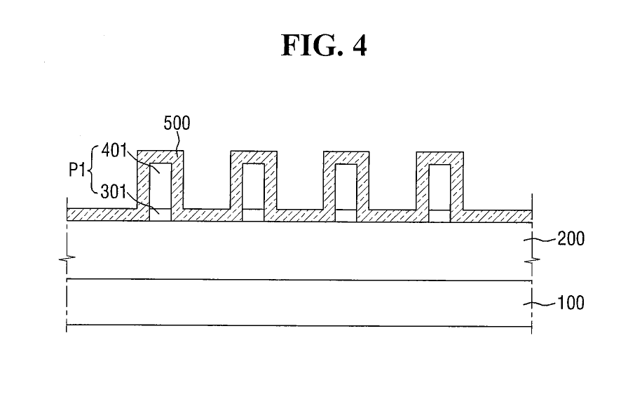

Referring to FIG. 4, the spacer layer 500 may be conformally formed on the first patterns P1. That is, the spacer layer 500 may be deposited and formed to cover an upper portion of the etching layer 200 and sidewalls and upper surfaces of the first patterns P1. The spacer layer 500 may be formed of a material having a high etch selection ratio with respect to the first patterns P1. In particular, the spacer layer 500 may be formed using a middle temperature oxide (MTO), a high temperature oxide (HTO) or a silicon oxide, such as an ALD oxide.

Referring to FIG. 5, the upper surfaces of the first patterns P1 may be exposed by removing portions of the spacer layer 500. In the removing of portions of the spacer layer 500, upper portions of the spacer layer 500 may be removed using an etch-back process. That is, by the etch-back process, the spacer layer patterns 501 may only remain on the sidewalls of the first patterns P1, and portions of the spacer layer 500 formed on the upper surfaces of the, first patterns P1 as well as on portions of an upper surface of the etching layer 200 may be removed.

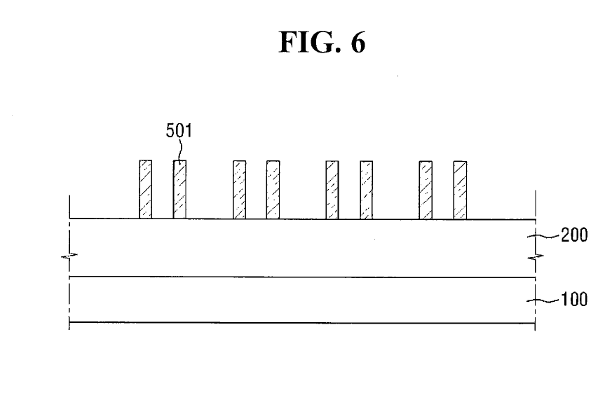

Referring to FIG. 6, the first patterns P1 exposed by the spacer layer patterns 501 may be removed. The spacer layer patterns 501 may be formed of a material having a high etch selection ratio with respect to the first patterns P1. Thus, a plurality of the first patterns P1 may be removed using an etchant that does not etch the spacer layer patterns 501 while etching the first patterns P1.

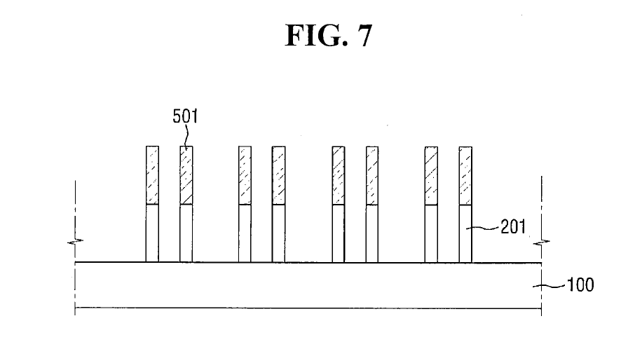

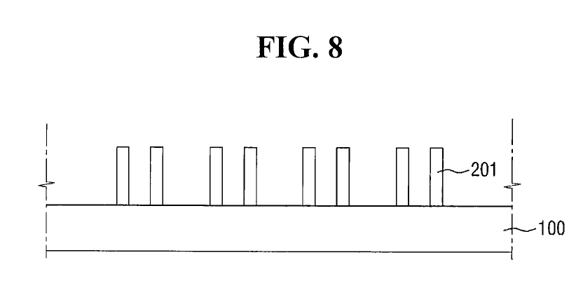

Referring to FIG. 7 and FIG. 8, portions of the etching layer 200 may be removed by using the spacer layer patterns 501 as a mask. That is, the etching layer 200 may be etched by using the spacer layer patterns 501 as a mask to thereby form the patterns 201. After the forming of the patterns 201, the spacer layer patterns 501 may be removed, thereby completing the target patterns 201 on the substrate 100.

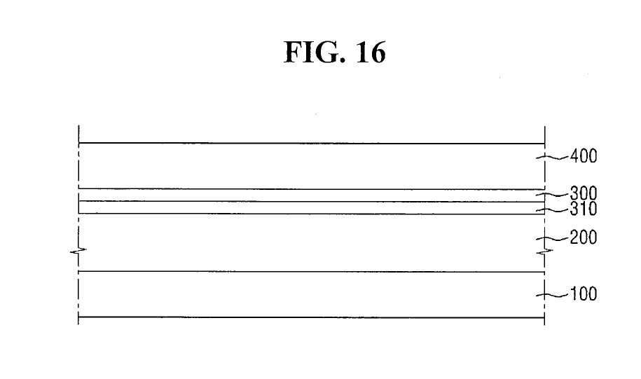

Hereinafter, with reference to FIG. 16 through FIG. 21, operations for forming a pattern of a semiconductor device according to some embodiments of the present inventive concept will be described.

FIG. 16 through FIG. 21 are intermediate-level views illustrating operations for forming a pattern of a semiconductor device according to some embodiments of the present inventive concept. For convenience of explanation, a description of portions substantially identical to those of the operations for forming a pattern of a semiconductor device according to some embodiments of the present inventive concept will be omitted.

Referring to FIG. 16, an etching layer 200 (a layer to be etched), a second anti-reflection layer 310, a first anti-reflection layer 300, and a photoresist layer 400 may be sequentially stacked on a substrate 100. For example, the first anti-reflection layer 300 may be an organic anti-reflection layer and may contain an anti reflective coating (ARC) material. The second anti-reflection layer 310 may be an inorganic anti-reflection layer and may contain a silicon oxynitride (SiON). The second anti-reflection layer 310 may be formed through a CVD process or the like, using a silicon oxynitride.

The first anti-reflection layer 300 may contain a photosensitive material and may be disposed between the second anti-reflection layer 310 and the photoresist layer 400. In some embodiments according to the present inventive concept, a hard mask layer such as a spin-on hard mask (SOH), an amorphous carbon layer (ACL) or the like is not used and photoresist patterns 402 may be used as mandrel patterns.

The substrate 100 and the etching layer 200 may include substantially identical configurations to those described in the method for forming a pattern of a semiconductor device according to some embodiments of the present inventive concept.

The second anti-reflection layer 310 may be formed on the etching layer 200 and the first anti-reflection layer 300 may be formed on the second anti-reflection layer 310. The first anti-reflection layer 300 and the second anti-reflection layer 310 may serve to prevent diffused reflection in a photolithography process for forming the photoresist patterns 402.

In some embodiments according to the present inventive concept, the first anti-reflection layer 300 may contain a photosensitive material. In order to form various patterns by patterning the etching layer 200, sidewalls of mask patterns (that is, spacer layer patterns 511) serving as a mask desirably have a substantially vertical slope. In the case that the mask patterns are asymmetrically and irregularly formed in profile, the patterns formed on the substrate 100 may also have asymmetrical and irregular shapes.

When the spacer layer patterns 511 are formed using the photoresist patterns 402 as mandrel patterns, it is required to form the photoresist patterns 402 in sidewall shapes having a vertical slope, like a hard mask layer used in a general MPT process. Thus, in some embodiments according to the present inventive concept, the first anti-reflection layer 300 having photosensitivity may be used.

For example, in the case that a photo acid generator (PAG) is contained in the first anti-reflection layer 300 as a photosensitive material, acid (that is, hydrogen ions) may be generated in an exposure region of the first anti-reflection layer 300 by photoreaction of the PAG. The generated acid may be spread to a lower portion of the photoresist layer 400 to increase an acid concentration in the lower portion of the photoresist layer 400 having a relatively insufficient acid concentration. Accordingly, improvements may be made in such a manner that the photoresist patterns 402 formed in the photolithography process have sidewall shapes having a vertical slope.

Referring to FIG. 16 again, the photoresist layer 400 may be formed on the first anti-reflection layer 300.

The photoresist layer 400 may be formed of a material corresponding to an ArF-i (193 nm-i) or VUV (147 nm) chemically amplified resist. For example, the photoresist layer 400 may be formed of an acrylate polymer, a methacrylate polymer, a cyclo olefin-maleic anhydride copolymer (hereinafter, referred to as ‘a COMA polymer’) or hybrid polymers thereof.

The photoresist layer 400 may be formed by a spin-on deposition method, using the photoresist material. In this case, the photoresist layer 400 may be formed to have a thickness such that the first anti-reflection layer 300 may be etched using the photoresist patterns 402 formed subsequently to the photoresist layer 400. For example, the photoresist material may be spin-coated and may be formed to have a thickness of 80 nm to 150 nm.

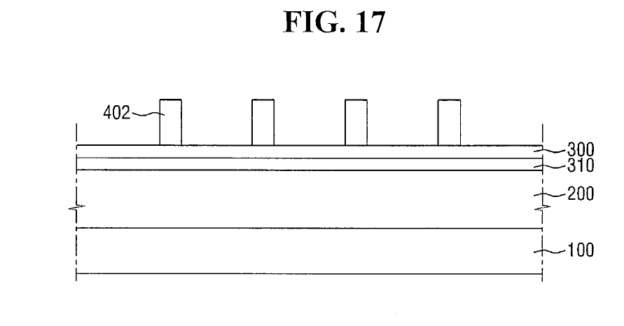

Referring to FIG. 17, the photoresist patterns 402 may be formed by etching the photoresist layer 400. In this case, by the first anti-reflection layer 300 disposed below the photoresist patterns 402, the photoresist patterns 402 may be formed to have sidewall shapes having a substantially vertical slope.

In the exposure process, a light source such as ArF-i (193 nm-i) or VUV (147 nm) may be used. For example, the exposure process may be performed with energy of 10 mJ/cm²to 50 mJ/cm² using an ArF-i light source. A pre-bake process may be further performed prior to the exposure process. In addition, even after the exposure process, a post-bake process may be further performed. The bake process may be performed at a temperature of 90° C. to 110° C. Subsequent to the exposure process, a development process may be performed on an exposure region of the photoresist layer 400 to thereby form the photoresist patterns 402.

The development process may be performed using approximately 2.4 wt % of a tetramethyl ammonia hydroxide (TMAH) solution, which is an alkaline developer. After performing the development process using the developer, a washing process of removing the developer using a conditioner solution may be further performed. The conditioner solution may be deionized water (DIW).

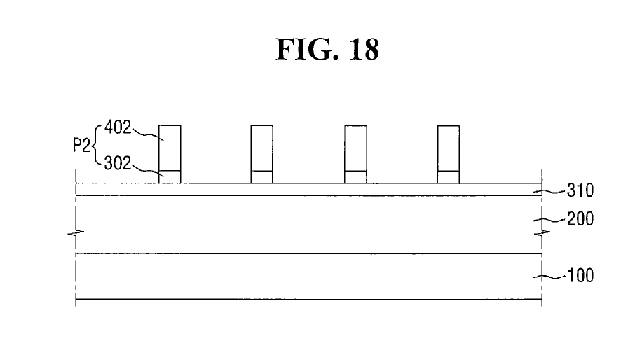

Referring to FIG. 18, the first anti-reflection layer 300 may be etched using the photoresist patterns 402 as a mask to thereby form second patterns P2. The second patterns P2 may include the photoresist patterns 402 and first anti-reflection layer patterns 302. That is, the second patterns P2 may include portions of the photoresist layer 400 and portions of the first anti-reflection layer 300.

In this case, the forming of the second patterns P2 may be completed by removing portions of the photoresist layer 400 in an in-situ process and removing portions of the first anti-reflection layer 300, in sequence. In addition, the second patterns P2 may be completed by removing portions of the photoresist layer 400 using a photolithography process and removing portions of the first anti-reflection layer 300 using the remainder portions (that is, the photoresist patterns 402) of the photoresist layer 400 as a mask.

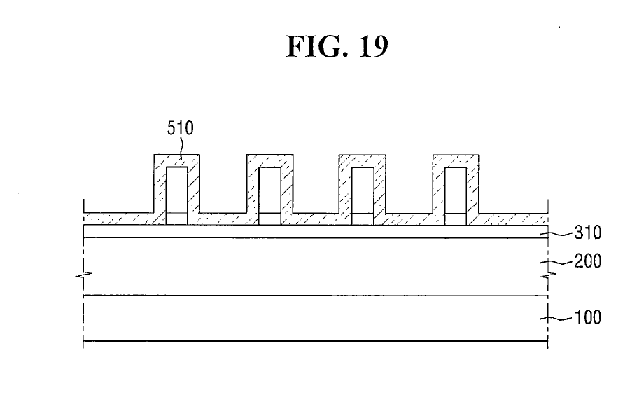

Referring to FIG. 19, a spacer layer 510 may be conformally formed on the second patterns P2. That is, the spacer layer 510 may be deposited and formed to cover an upper portion of the second anti-reflection layer 310 and sidewalls and upper surfaces of the second patterns P2. The spacer layer 510 may be formed of a material having a high etch selection ratio with respect to the second patterns P2. In particular, the spacer layer 510 may be formed using a middle temperature oxide (MTO), a high temperature oxide (HTO) or a silicon oxide such as an ALD oxide.

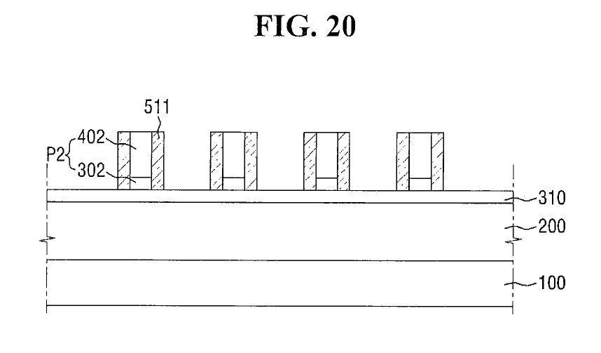

Referring to FIG. 20, the upper surfaces of the second patterns P2 may be exposed by removing portions of the spacer layer 510. In the removing of portions of the spacer layer 510, upper portions of the spacer layer 510 may be removed using an etch-back process. That is, by the etch-back process, the spacer layer patterns 511 may only remain on the sidewalls of the second patterns P2, and portions of the spacer layer 510 formed on the upper surfaces of the second patterns P2 as well as on portions of an upper surface of the second anti-reflection layer 310 may be removed.

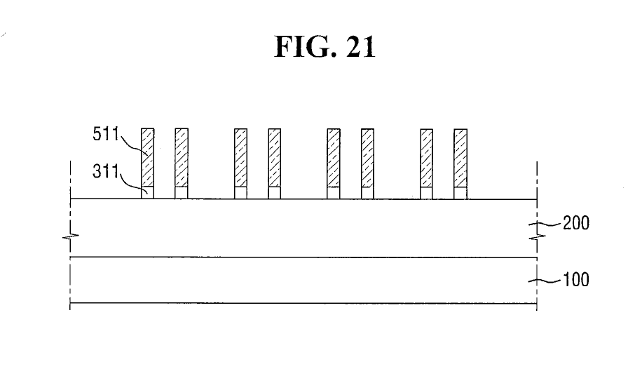

Referring to FIG. 21, the second patterns P2 exposed by the spacer layer patterns 511 may be removed. The spacer layer patterns 511 may be formed of a material having a high etch selection ratio with respect to the second patterns P2. Thus, a plurality of the second patterns P2 may be removed using an etchant that does not etch the spacer layer patterns 511 while etching the second patterns P2. In addition, portions of the second anti-reflection layer 310 may be removed by using the spacer layer patterns 511 as a mask to thereby form second anti-reflection layer patterns 311. In a subsequent process, the etching layer 200 may be etched by using the second anti-reflection layer patterns 311 as a mask, thereby forming target patterns on the substrate 100.

Hereinafter, a NAND flash memory device formed by using the method for forming a pattern of a semiconductor device according to some embodiments of the present inventive concept will be explained.

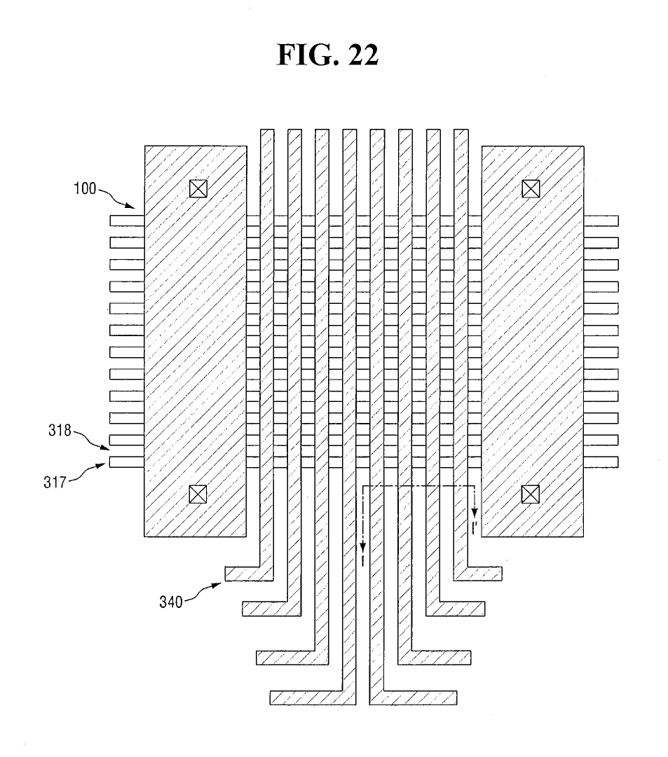

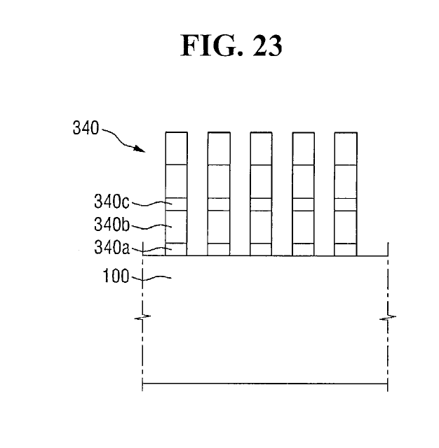

FIG. 22 is a plan view of a NAND flash memory device formed by using the method for forming a pattern of a semiconductor device according to some embodiments of the present inventive concept. FIG. 23 is a cross-sectional view taken along line I-I′ of FIG. 22.

Referring to FIG. 22 and FIG. 23, an upper surface of a monocrystalline silicon substrate 100 may classified into an active region for implementing circuits and an element isolation region for electrically isolating respective elements from each other.

The active region may include active patterns 318 repeatedly disposed and having a linear shape extended in a second direction. The active patterns 318 may have a narrow line width equal to a limit line width of a photolithography process. Trenches may be provided between the active patterns 318 and may be filled with an insulating material, such that element isolation patterns 317 may be provided.

Cell transistors 332, word lines 340 and selection transistors 334 may be provided on the active patterns 318.

The cell transistors 332 may include tunnel oxide layer patterns 340a, floating gate electrodes 340b, dielectric layer patterns 340c and control gate electrodes 340. Specifically, the tunnel oxide layer patterns 340a may be formed on surfaces of the active patterns 318. The floating gate electrodes 340b may have isolated pattern shapes and may be regularly disposed on the tunnel oxide layer patterns 340a. The dielectric layer patterns 340c may be provided on the floating gate electrodes 340b. In addition, the control gate electrodes 340 provided on the dielectric layer patterns 340c may have linear shapes extended in a first direction perpendicular to the second direction and may be opposite to the floating gate electrodes 340b. The control gate electrodes 340 may be used in common with the word lines 340.

In the case of the NAND flash memory device, the element isolation patterns and the control gate electrodes may have a linearly, repeated pattern shape. Thus, in a patterning process for forming the element isolation patterns and the control gate electrodes, the method for forming a pattern of a semiconductor device as described above may be used.

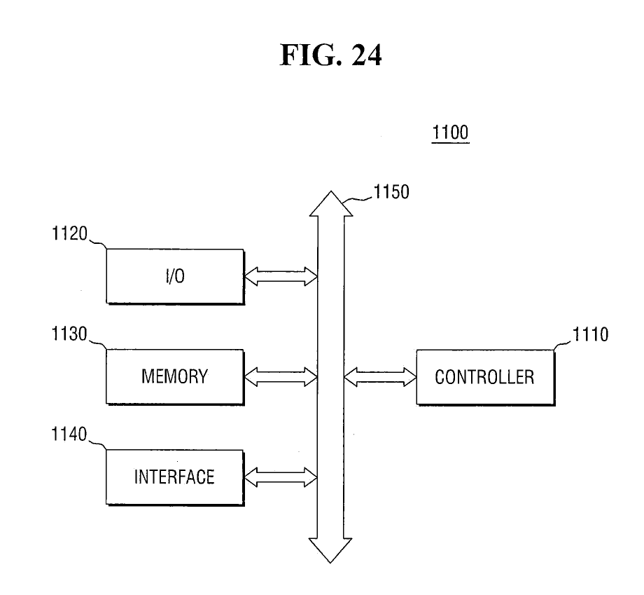

FIG. 24 is a block diagram of an electronic system including a semiconductor device formed using the method for forming a pattern of a semiconductor device according to some embodiments of the present inventive concept.

Referring to FIG. 24, an electronic system 1100 according to some embodiments of the present inventive concept may include a controller 1110, an input/output device (I/O) 1120, a memory device 1130, an interface 1140 and a bus 1150.

The controller 1110, the input/output device (I/O) 1120, the memory device 1130, and/or the interface 1140 may be coupled to each other through the bus 1150. The bus 1150 may correspond to a path through which data is transferred.

The controller 1110 may include at least one of a microprocessor, a digital signal processor, a microcontroller and logic devices capable of performing similar functions thereto.

The input/output device (I/O) 1120 may include a keypad, keyboard, a display and the like. The memory device 1130 may store data and/or a command or the like therein.

The interface 1140 may transmit data to communication networks and receive data from the communication networks. The interface 1140 may have a wired or wireless form. For example, the interface 1140 may include an antenna, a wired/wireless transceiver and the like. In addition, the electronic system 1100 may be an operating memory for improving operations of the controller 1110 and may further include a high speed dynamic random access memory and/or static random access memory or the like.

The semiconductor devices according to the foregoing exemplary embodiments of the present inventive concept may be provided within the memory device 1130 or may be provided as parts of the controller 1110, the input/output device (I/O) 1120 and the like.

The electronic system 1100 may be applied to personal digital assistants (PDA), portable computers, web tablets, wireless phones, mobile phones, digital music players, memory cards, or all electrical products capable of transmitting and receiving information in wireless environments.

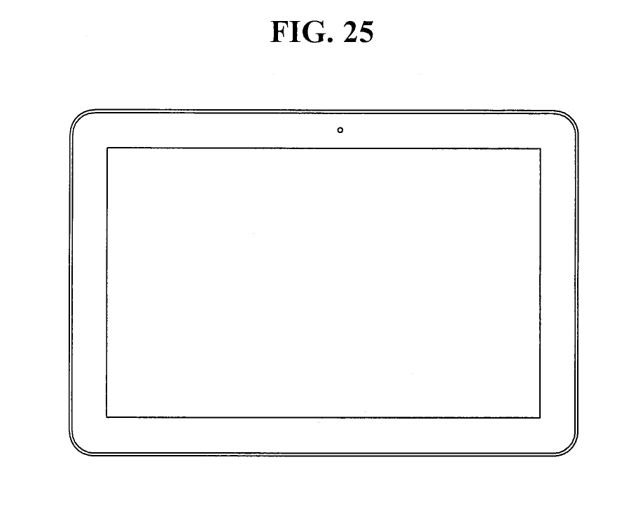

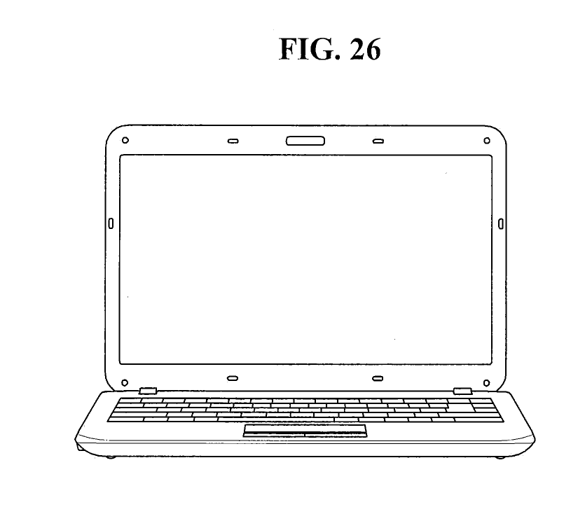

FIG. 25 and FIG. 26 are exemplary semiconductor systems to which a semiconductor device formed using the method for forming a pattern of a semiconductor device according to some embodiments of the present inventive concept is applicable.

FIG. 25 is a view illustrating a tablet PC and FIG. 26 is a view illustrating a laptop computer. At least one of the semiconductor devices according to the exemplary embodiments of the present inventive concept may be used in the tablet PC, the laptop computer and the like. It may be apparent to a person having ordinary skill in the art that the semiconductor devices according to some embodiments of the present inventive concept may be applied to other integrated circuit devices (not shown).

While exemplary embodiments have been shown and described above, it will be apparent to those skilled in the art that modifications and variations could be made without departing from the spirit and scope of the present inventive concept as defined by the appended claims.

What is claimed is:

1. A method comprising:
providing a substrate comprising an etching layer, an anti-reflection layer containing a photosensitive material directly on the etching layer, and a photoresist layer directly on the anti-reflection layer;
forming a first pattern by etching the photoresist layer and the anti-reflection layer;
forming a spacer layer on upper and sidewall surfaces of the first pattern;
removing a portion of the spacer layer to expose the upper surface of the first pattern;
removing the exposed first pattern; and
patterning the etching layer using remaining portions of the spacer layer as a mask to form a second pattern.

2. The method of claim 1, wherein the anti-reflection layer provides hydrogen ions to the photoresist layer.

3. The method of claim 1, wherein the anti-reflection layer includes a photo acid generator (PAG).

4. The method of claim 1, wherein the first pattern includes a portion of the photoresist layer and a portion of the anti-reflection layer.

5. The method of claim 1, wherein forming the first pattern comprises removing a portion of the photoresist layer in an in-situ process and removing a portion of the anti-reflection layer in successive processes.

6. The method of claim 1, wherein forming the first pattern is completed by removing a portion of the photoresist layer using a photolithography process and removing a portion of the anti-reflection layer using a remainder of the photoresist layer as a mask.

7. The method of claim 1, wherein an upper portion of the spacer layer is removed using an etch-back process.

8. The method of claim 1, wherein the anti-reflection layer has a multilayer structure.

9. A method comprising:
forming an etching layer on a substrate;
forming an inorganic anti-reflection layer directly on the etching layer;
forming an organic anti-reflection layer directly on the inorganic anti-reflection layer;
forming a photoresist layer directly on the organic anti-reflection layer;
forming a first pattern by removing portions of the organic anti-reflection layer and the photoresist layer;
forming a spacer on a sidewall of the first pattern;
removing the first pattern; and
removing a portion of the inorganic anti-reflection layer using the spacer as a mask to form a second pattern.

10. The method of claim 9, wherein the organic anti-reflection layer provides hydrogen ions to the photoresist layer.

11. The method of claim 9, wherein the organic anti-reflection layer includes a photosensitive material.

12. The method of claim 11, wherein the organic anti-reflection layer includes a photo acid generator (PAG).

13. The method of claim 9, wherein forming the first pattern comprises removing a portion of the photoresist layer in an in-situ process and removing a portion of the organic anti-reflection layer in successive processes.

14. The method of claim 9, wherein forming the first pattern comprises removing a portion of the photoresist layer using a photolithography process and removing a portion of the organic anti-reflection layer using a remainder of the photoresist layer as a mask.

15. The method of claim 9, further comprising patterning the etching layer using the second pattern as a mask.

16. A method comprising:
forming an anti-reflection layer containing a photosensitive material directly on an etching layer;
forming a photoresist layer directly on the anti-reflection layer;
removing portions of the photoresist layer and the anti-reflection layer to form a pattern;
forming spacers on sidewalls of the pattern;
removing the pattern; and
patterning the etching layer using the spacers as a mask.

17. The method of claim 16, wherein forming an anti-reflection layer comprises:
forming an inorganic anti-reflection layer directly on the etching layer; and
forming an organic anti-reflection layer directly on the inorganic anti-reflection layer.

18. The method of claim 16, wherein the anti-reflection layer provides hydrogen ions to the photoresist layer.

19. The method of claim 16, wherein the anti-reflection layer includes a photosensitive material.

20. The method of claim 16, wherein the organic anti-reflection layer includes a photo acid generator (PAG).
